(19) United States
(12) Patent Application Publication
(10) Pub. No.: US 2023/0137269 A1
(43) Pub. Date: May 4, 2023

(54) GOA CIRCUIT, DISPLAY PANEL, AND DISPLAY DEVICE

(71) Applicant: WUHAN CHINA STAR OPTOELECTRONICS TECHNOLOGY CO., LTD., Wuhan (CN)

(72) Inventor: Chao TIAN, Wuhan (CN)

(73) Assignee: WUHAN CHINA STAR OPTOELECTRONICS TECHNOLOGY CO., LTD., Wuhan (CN)

(21) Appl. No.: 16/970,641

(22) PCT Filed: Jun. 24, 2020
(86) PCT No.: PCT/CN2020/098275

§ 371 Date: Aug. 18, 2020

(30) Foreign Application Priority Data
Jun. 1, 2020 (CN) 202010485090.3

(51) Int. Cl. G09G 3/36

(52) U.S. Cl. CPC G09G 3/3677; G09G 2300/0852

(57) ABSTRACT

A GOA circuit, a display panel, and a display device are provided. The GOA circuit includes a second pull-down module. The second pull-down module includes a third thin film transistor, a fourth thin film transistor, and a fifth thin film transistor. An input terminal of the third thin film transistor receives a constant high voltage level signal. A control terminal of the third thin film transistor receives a second control signal. An output terminal of the third thin film transistor, an input terminal of the fourth thin film transistor, and an input terminal of the fifth thin film transistor are connected together.

This application claims the priority of Chinese Patent Application No. 202010485090.3, entitled “GOA CIRCUIT, DISPLAY PANEL, AND DISPLAY DEVICE”, filed on Jun. 1, 2020 in the CNIPA (National Intellectual Property Administration, PRC), the disclosure of which is incorporated herein by reference in its entirety.

### TECHNICAL FIELD

The present disclosure relates to a display technology field, and more particularly to a GOA circuit, a display panel, and a display device.

### BACKGROUND

Currently, liquid crystal display devices serving as parts of electronic devices have been applied to various electronic products. A GOA circuit is an important component in a liquid crystal display device. Gate Driver On Array (GOA) is a technology which uses a conventional thin film transistor array process of a liquid crystal display device to fabricate gate circuits of row scan drivers on an array substrate to implement a driving manner of scanning gate electrodes row-by-row.

Based on a display panel of Low Temperature Poly-Silicon (LTPS), thin film transistors used in the panel can be divided into N-type thin film transistors, P-type thin film transistors, and C-type thin film transistors including the N-type thin film transistors and P-type thin film transistors. Similarly, GOA circuits are divided into N-type thin film transistor circuits, P-type thin film transistor circuits, and C-type thin film transistor circuits. Compared to the C-type thin film transistor circuits, the N-type thin film transistor circuits have great benefit of increasing yield and decreasing cost because a photomask process of P-type doping can be saved. Accordingly, developing stable N-type thin film transistor circuits has realistic industry requirements. Current N-type thin film transistor circuits includes different drive methods including 2 phases, 4 phases, 6 phases, and 8 phases. Different numbers of phases mean that different numbers of clock signals are required. To correspond to requirements of narrow bezel and full screen, a circuit of 2 phases is suitable for product requirements. Generally, the circuit of 2 phases introduces an inverter design for N-type thin film transistors. However, a competitive relationship exists in the simple inverter design for N-type thin film transistors obviously. Point Q is not stable easily, so that stability of a GOA circuit is decreased.

In the prior art, stability of a GOA circuit in a display panel is not high.

### SUMMARY OF DISCLOSURE

Embodiments of the present disclosure provide a GOA circuit, a display panel, and a display device capable of increasing stability of the GOA circuit.

To solve the above-mentioned problem, in a first aspect, the present disclosure provides a GOA circuit, the GOA circuit includes m cascaded GOA units, and an nth stage GOA unit of the GOA units includes:

a first node signal control module configured to input a voltage to a first node according to an (n+1)th stage clock signal, wherein m≥n≥1;

a first pull-down module configured to pull down a voltage level of the first node;

a forward-backward scan control module configured to input a first control signal to the first pull-down module and a second node according to a forward-backward scan control signal, an (n−1)th stage gate drive signal, and an (n+1)th stage gate drive signal; and

a second pull-down module, the second pull-down module including a third thin film transistor, a fourth thin film transistor, and a fifth thin film transistor, wherein an input terminal of the third thin film transistor receives a constant high voltage level signal, a control terminal of the third thin film transistor receives a second control signal, an output terminal of the third thin film transistor, an input terminal of the fourth thin film transistor, and an input terminal of the fifth thin film transistor are connected together, an output terminal of the fourth thin film transistor is connected to the second node, and an output terminal of the fifth thin film transistor receives a constant low voltage level signal.

The second control signal is the (n−1)th stage gate drive signal.

The control terminal of the third thin film transistor is connected to the second node to receive the second control signal.

The third thin film transistor, the fourth thin film transistor, and the fifth thin film transistor are N-type thin film transistors.

The first pull-down module includes a sixth thin film transistor, a control terminal of the sixth thin film transistor is connected to the forward-backward scan control module, an input terminal of the sixth thin film transistor receives the constant low voltage level signal, and an output terminal of the sixth thin film transistor is connected to the first node.

The forward-backward scan control module includes a first thin film transistor and a second thin film transistor;

an input terminal of the first thin film transistor receives a forward scan signal, and a control terminal of the first thin film transistor receives the (n−1)th stage gate drive signal;

an input terminal of the second thin film transistor receives a backward scan signal, and a control terminal of the second thin film transistor receives the (n+1)th stage gate drive signal; and

an output terminal of the first thin film transistor, an output terminal of the second thin film transistor, and a control terminal of the sixth thin film transistor are connected together.

The first node signal control module includes an eighth thin film transistor, the output terminal of the first thin film transistor, the output terminal of the second thin film transistor, and a control terminal of the output terminal of the eighth thin film transistor are connected together, an input terminal of the eighth thin film transistor receives the constant high voltage level signal, and an output terminal of the eighth thin film transistor is connected to the first node.

The nth stage GOA unit includes a first capacitor and a second capacitor, one terminal of the first capacitor is connected to the second node, the other terminal of the first capacitor receives the constant low voltage level signal, one terminal of the second capacitor is connected to the first node, and the other terminal of the second capacitor receives the constant low voltage level signal.

To solve the above-mentioned problem, in a second aspect, the present disclosure provides a display panel, the display panel includes a GOA circuit, the GOA circuit includes m cascaded GOA units, and an nth stage GOA unit of the GOA units includes:

a first node signal control module configured to input a voltage to a first node according to an (n+1)th stage clock signal, wherein m≥n≥1;

a first pull-down module configured to pull down a voltage level of the first node;

a forward-backward scan control module configured to input a first control signal to the first pull-down module and a second node according to a forward-backward scan control signal, an (n−1)th stage gate drive signal, and an (n+1)th stage gate drive signal; and

a second pull-down module, the second pull-down module including a third thin film transistor, a fourth thin film transistor, and a fifth thin film transistor, wherein an input terminal of the third thin film transistor receives a constant high voltage level signal, a control terminal of the third thin film transistor receives a second control signal, an output terminal of the third thin film transistor, an input terminal of the fourth thin film transistor, and an input terminal of the fifth thin film transistor are connected together, an output terminal of the fourth thin film transistor is connected to the second node, and an output terminal of the fifth thin film transistor receives a constant low voltage level signal.

The second control signal is the (n−1)th stage gate drive signal.

The control terminal of the third thin film transistor is connected to the second node to receive the second control signal.

The third thin film transistor, the fourth thin film transistor, and the fifth thin film transistor are N-type thin film transistors.

The first pull-down module includes a sixth thin film transistor, a control terminal of the sixth thin film transistor is connected to the forward-backward scan control module, an input terminal of the sixth thin film transistor receives the constant low voltage level signal, and an output terminal of the sixth thin film transistor is connected to the first node.

The forward-backward scan control module includes a first thin film transistor and a second thin film transistor;

an input terminal of the first thin film transistor receives a forward scan signal, and a control terminal of the first thin film transistor receives the (n−1)th stage gate drive signal;

an input terminal of the second thin film transistor receives a backward scan signal, and a control terminal of the second thin film transistor receives the (n+1)th stage gate drive signal; and

an output terminal of the first thin film transistor, an output terminal of the second thin film transistor, and a control terminal of the sixth thin film transistor are connected together.

The first node signal control module includes an eighth thin film transistor, the output terminal of the first thin film transistor, the output terminal of the second thin film transistor, and a control terminal of the output terminal of the eighth thin film transistor are connected together, an input terminal of the eighth thin film transistor receives the constant high voltage level signal, and an output terminal of the eighth thin film transistor is connected to the first node.

The nth stage GOA unit includes a first capacitor and a second capacitor, one terminal of the first capacitor is connected to the second node, the other terminal of the first capacitor receives the constant low voltage level signal, one terminal of the second capacitor is connected to the first node, and the other terminal of the second capacitor receives the constant low voltage level signal.

To solve the above-mentioned problem, in a third aspect, the present disclosure provides a display device, the display device includes GOA circuit, the GOA circuit includes m cascaded GOA units, and an nth stage GOA unit of the GOA units includes:

a first node signal control module configured to input a voltage to a first node according to an (n+1)th stage clock signal, wherein m≥n≥1;

a first pull-down module configured to pull down a voltage level of the first node;

a forward-backward scan control module configured to input a first control signal to the first pull-down module and a second node according to a forward-backward scan control signal, an (n−1)th stage gate drive signal, and an (n+1)th stage gate drive signal; and

a second pull-down module, the second pull-down module including a third thin film transistor, a fourth thin film transistor, and a fifth thin film transistor, wherein an input terminal of the third thin film transistor receives a constant high voltage level signal, a control terminal of the third thin film transistor receives a second control signal, an output terminal of the third thin film transistor, an input terminal of the fourth thin film transistor, and an input terminal of the fifth thin film transistor are connected together, an output terminal of the fourth thin film transistor is connected to the second node, and an output terminal of the fifth thin film transistor receives a constant low voltage level signal.

The second control signal is the (n−1)th stage gate drive signal.

The control terminal of the third thin film transistor is connected to the second node to receive the second control signal.

The third thin film transistor, the fourth thin film transistor, and the fifth thin film transistor are N-type thin film transistors.

Beneficial effect is described as follows. Differing from the prior art, the present disclosure provides a GOA circuit. The GOA circuit includes m cascaded GOA units. An nth stage GOA unit of the GOA units includes: a first node signal control module configured to input a voltage to a first node according to an (n+1)th stage clock signal, wherein m≥n≥1; a first pull-down module configured to pull down a voltage level of the first node; a forward-backward scan control module configured to input a first control signal to the first pull-down module and a second node according to a forward-backward scan control signal, an (n−1)th stage gate drive signal, and an (n+1)th stage gate drive signal; and a second pull-down module, the second pull-down module including a third thin film transistor, a fourth thin film transistor, and a fifth thin film transistor, wherein an input terminal of the third thin film transistor receives a constant high voltage level signal, a control terminal of the third thin film transistor receives a second control signal, an output terminal of the third thin film transistor, an input terminal of the fourth thin film transistor, and an input terminal of the fifth thin film transistor are connected together, an output terminal of the fourth thin film transistor is connected to the second node, and an output terminal of the fifth thin film transistor receives a constant low voltage level signal. In the present disclosure, when the voltage level of the first node is increased because a competitive relationship of controlling the first node by the first node signal control module and the first pull-down module changes, the third thin film transistor and the fourth thin film transistor are turned on simultaneously. The second node (that is, point Q) receives the constant high voltage level signal via the third thin film transistor and the fourth thin film transistor, thereby ensuring that the point Q remains at a high voltage level and increasing stability of the GOA circuit.

### BRIEF DESCRIPTION OF DRAWINGS

The technical solution, as well as other beneficial advantages, of the present disclosure will become apparent from the following detailed description of embodiments of the present disclosure, with reference to the attached drawings.

FIG. 1 illustrates a structural diagram of an nth stage GOA unit in a GOA circuit provided by an embodiment of the present disclosure.

FIG. 2 illustrates a structural diagram of an nth stage GOA unit in a GOA circuit provided by another embodiment of the present disclosure.

FIG. 3 illustrates a structural diagram of a two-clock signal architecture including an nth stage GOA unit and an (n+1)th stage GOA unit in a GOA circuit provided by an embodiment of the present disclosure.

FIG. 4 illustrates a signal timing diagram of the two-clock signal architecture including the nth stage GOA unit and the (n+1)th stage GOA unit in the GOA circuit in FIG. 3.

### DETAILED DESCRIPTION OF EMBODIMENTS

A clear and complete description of the technical schemes in the embodiments of the present disclosure is made in conjunction with the accompanying drawings in the embodiments of the present disclosure. The described embodiments are merely a part and not all of the embodiments of the present disclosure. Based on the embodiments of the present disclosure, all other embodiments acquired by those skilled in the art without any inventive efforts are within the scope of protection of the present disclosure.

In the description of the present disclosure, it should be understood that orientations or position relationships indicated by the terms “center”, “longitudinal”, “lateral”, “length”, “width”, “thickness”, “upper”, “lower”, “front”, “rear”, “left”, “right”, “vertical”, “horizontal”, “top”, “bottom”, “inside”, and “outside” are based on orientations or position relationships illustrated in the drawings. The terms are used to facilitate and simplify the description of the present disclosure, rather than indicate or imply that the devices or elements referred to herein is required to have specific orientations or be constructed or operates in the specific orientations. Accordingly, the terms should not be construed as limiting the present disclosure. Furthermore, the terms “first” and “second” are for descriptive purposes only and should not be construed as indicating or implying relative importance or implying the number of technical features. As such, the features defined by the term “first” and “second” may include one or more of the features explicitly or implicitly. In the description of the present disclosure, the term “more” refers two or more than two, unless otherwise specifically defined.

The word “exemplary” is used herein to mean “serving as an example, instance, or illustration.” Any embodiment described herein as “exemplary” is not necessarily to be construed as preferred or advantageous over other embodiments. The following description is presented to enable those skilled in the art to make and use the present disclosure. Details are set forth in the following description for purpose of explanation. It should be appreciated that those skilled in the art would realize that the present disclosure may be practiced without the use of these specific details. In other instances, well known structures and processes are not elaborated in order not to obscure the description of the present disclosure with unnecessary details. Thus, the present disclosure is not intended to be limited by the embodiments shown, but is to be accorded with the widest scope consistent with the principles and features disclosed herein.

An embodiment of the present disclosure provides a GOA circuit. The GOA circuit includes m cascaded GOA units. An nth stage GOA unit of the GOA units includes: a first node signal control module configured to input a voltage to a first node according to an (n+1)th stage clock signal, wherein m≥n≥1; a first pull-down module configured to pull down a voltage level of the first node; a forward-backward scan control module configured to input a first control signal to the first pull-down module and a second node according to a forward-backward scan control signal, an (n−1)th stage gate drive signal, and an (n+1)th stage gate drive signal; and a second pull-down module, the second pull-down module including a third thin film transistor, a fourth thin film transistor, and a fifth thin film transistor, wherein an input terminal of the third thin film transistor receives a constant high voltage level signal, a control terminal of the third thin film transistor receives a second control signal, an output terminal of the third thin film transistor, an input terminal of the fourth thin film transistor, and an input terminal of the fifth thin film transistor are connected together, an output terminal of the fourth thin film transistor is connected to the second node, and an output terminal of the fifth thin film transistor receives a constant low voltage level signal. In the present disclosure, when the voltage level of the first node is increased because a competitive relationship of controlling the first node by the first node signal control module and the first pull-down module changes, the third thin film transistor and the fourth thin film transistor are turned on simultaneously. The second node (that is, point Q) receives the constant high voltage level signal via the third thin film transistor and the fourth thin film transistor, thereby ensuring that the point Q remains at a high voltage level and increasing stability of the GOA circuit. The GOA circuits in accordance with embodiments of the present disclosure can be applied to various display panels and will be described in detail as follows.

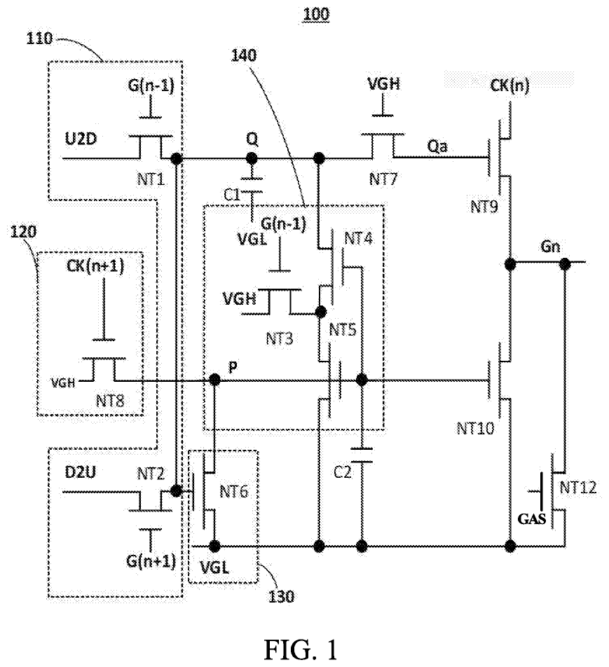

Please refer to FIG. 1. FIG. 1 illustrates a structural diagram of an nth stage GOA unit in a GOA circuit provided by an embodiment of the present disclosure.

As shown in FIG. 1, in the present embodiment, the GOA circuit includes m cascaded GOA units. The nth stage GOA unit 100 of the GOA units includes a first node signal control module 120, a first pull-down module 130, a second pull-down module 140, and a forward-backward scan control module 120. The first node signal control module 120 is configured to input a voltage to a first node P according to an (n+1)th stage clock signal, wherein m≥n≥1. The forward-backward scan control module 120 is configured to input a first control signal to the first pull-down module 130 and a second node Q according to a forward-backward scan control signal, an (n−1)th stage gate drive signal G(n−1), and an (n+1)th stage gate drive signal G(n+1). The second pull-down module includes a third thin film transistor NT3, a fourth thin film transistor NT4, and a fifth thin film transistor NT5. An input terminal of the third thin film transistor NT3 receives a constant high voltage level signal VGH. A control terminal of the third thin film transistor NT3 receives a second control signal. An output terminal of the third thin film transistor NT3, an input terminal of the fourth thin film transistor NT4, and an input terminal of the fifth thin film transistor NT5 are connected together. An output terminal of the fourth thin film transistor NT4 is connected to the second node Q. An output terminal of the fifth thin film transistor NT5 receives a constant low voltage level signal VGL. When the voltage level of the first node P is increased because a competitive relationship of controlling the first node P by the first node signal control module 120 and the first pull-down module 130 changes, the third thin film transistor NT3 and the fourth thin film transistor NT4 are turned on simultaneously. The second node Q receives the constant high voltage level signal VGH via the third thin film transistor NT3 and the fourth thin film transistor NT4, thereby ensuring that the point Q remains at a high voltage level and increasing stability of the GOA circuit.

It is noted that in the present disclosure, the input terminals of the thin film transistors are source electrodes of the thin film transistors, the output terminals of the thin film transistors are drain electrodes of the thin film transistors, and the control terminals of the thin film transistors are gate electrodes of the thin film transistors. In some embodiments, the source electrodes and the drain electrodes can be exchanged according different practical situations. The present disclosure is not limited thereto.

In a specific embodiment, the first pull-down module 130 includes a sixth thin film transistor NT6. A control terminal of the sixth thin film transistor NT6 is connected to the forward-backward scan control module 120. An input terminal of the sixth thin film transistor NT6 receives the constant low voltage level signal VGL. An output terminal of the sixth thin film transistor NT6 is connected to the first node P. When the sixth thin film transistor NT6 is turned on, the constant low voltage level signal VGL is inputted to the first node P.

Further, the forward-backward scan control module 120 includes a first thin film transistor NT1 and a second thin film transistor NT2. An input terminal of the first thin film transistor NT1 receives a forward scan signal U2D. A control terminal of the first thin film transistor NT1 receives the (n−1)th stage gate drive signal G(n−1). An input terminal of the second thin film transistor NT2 receives a backward scan signal D2U. A control terminal of the second thin film transistor NT2 receives the (n+1)th stage gate drive signal. An output terminal of the first thin film transistor NT1, an output terminal of the second thin film transistor NT2, and a control terminal of the sixth thin film transistor NT6 are connected together.

When a display panel is scanned forward, the forward scan signal U2D is at a high voltage level and the backward scan signal D2U is at a low voltage level. Meanwhile, the GOA circuit scans from top to bottom row-by-row, that is, from the nth stage GOA unit 100 to an (n+1) stage GOA unit 200. In contrast, when the display panel is scanned backward, the forward scan signal U2D is at low high voltage level and the backward scan signal D2U is at a high voltage level. The GOA circuit scans from bottom to top row-by-row, that is, from the (n+1) stage GOA unit 200 to the nth stage GOA unit 100.

In the embodiment of the present disclosure, the first node signal control module 120 includes an eighth thin film transistor NT8. The output terminal of the first thin film transistor NT1, the output terminal of the second thin film transistor NT2, and a control terminal of the output terminal of the eighth thin film transistor NT8 are connected together. An input terminal of the eighth thin film transistor NT8 receives the constant high voltage level signal VGH. An output terminal of the eighth thin film transistor NT8 is connected to the first node P. The eighth thin film transistor NT8 is configured to output a high voltage level to the first node P.

Further, the nth stage GOA unit 100 includes a first capacitor C1 and a second capacitor C2. One terminal of the first capacitor C1 is connected to the second node Q. The other terminal of the first capacitor C1 receives the constant low voltage level signal VGL. One terminal of the second capacitor C2 is connected to the first node P. The other terminal of the second capacitor C2 receives the constant low voltage level signal VGL.

Further, the nth stage GOA unit 100 further includes a seventh thin film transistor NT7 and a ninth thin film transistor NT9. A control terminal of the seventh thin film transistor NT7 receives the constant high voltage level signal VGH. An input terminal of the seventh thin film transistor NT7 is connected to the second node Q. An output terminal of the seventh thin film transistor NT7 is connected to a control terminal of the ninth thin film transistor NT9. An input terminal of the ninth thin film transistor NT9 receives an nth stage clock signal CK(n). An output terminal of the ninth thin film transistor NT9 is configured to output a high voltage level to an nth stage drive signal Gn.

Further, the nth stage GOA unit 100 further includes a tenth thin film transistor NT10. A control terminal of the tenth thin film transistor NT10 is connected to the first node P. An input terminal of the tenth thin film transistor NT10 receives the constant low voltage level signal VGL. An output terminal of the tenth thin film transistor NT10 is connected to the output terminal of the ninth thin film transistor NT9 and configured to output a low voltage level to the nth stage drive signal Gn.

Further, the nth stage GOA unit 100 further includes a twelfth thin film transistor NT12. An input terminal of the twelfth thin film transistor NT12 receives the constant low voltage level signal VGL. A control terminal of the twelfth thin film transistor NT12 receives a global control signal. An output terminal of the twelfth thin film transistor NT12 is configured to pull down the nth stage drive signal Gn.

In the embodiment of the present disclosure, the first thin film transistor NT1, the second thin film transistor NT2, the third thin film transistor NT3, the fourth thin film transistor NT4, the fifth thin film transistor NT5, the sixth thin film transistor NT6, the seventh thin film transistor NT7, the eighth thin film transistor NT8, the ninth thin film transistor NT9, the tenth thin film transistor NT10, and the twelfth thin film transistor NT12 are N-type thin film transistors. Certainly, P-type thin film transistors or C-type thin film transistors may be used according to practical situations.

In the embodiment of the present disclosure, the second control signal is the (n−1)th stage gate drive signal G(n−1). Meanwhile, when the (n−1)th stage gate drive signal G(n−1) is at a high voltage level, the third thin film transistor NT3 is turned on. When the first node P is at a low voltage level, the fourth thin film transistor NT4 and the fifth thin film transistor NT5 are turned off. Meanwhile, the first node P and the second node work normally. When the voltage level of the first node P is increased because a competitive relationship of the sixth thin film transistor NT6 and the eighth thin film transistor NT8 changes, the third thin film transistor NT3 and the fourth thin film transistor NT4 are turned on simultaneously. The second node Q receives the constant high voltage level signal VGH via the third thin film transistor NT3 and the fourth thin film transistor NT4, thereby ensuring that the point Q remains at a high voltage level and increasing stability of the GOA circuit.

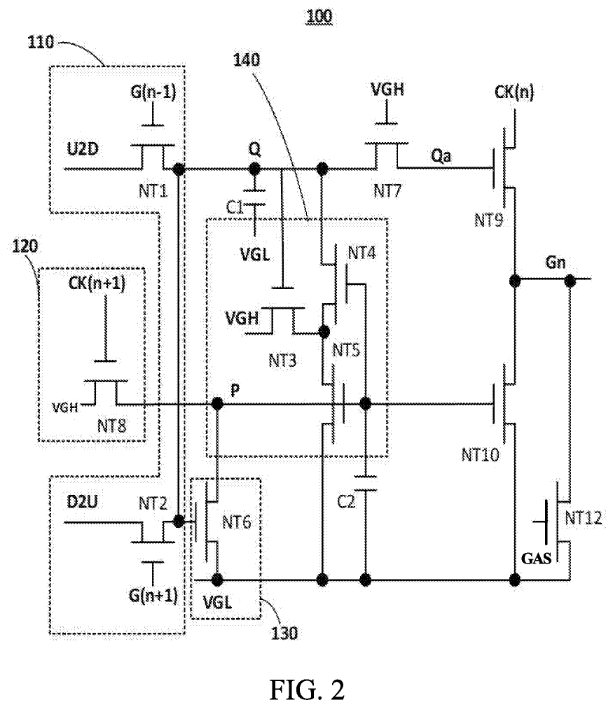

Please refer to FIG. 2 in accordance with another embodiment. FIG. 2 illustrates a structural diagram of an nth stage GOA unit in a GOA circuit provided by another embodiment of the present disclosure.

As shown in FIG. 2, a difference between the present embodiment and the embodiment in FIG. 1 is that the control terminal of the third thin film transistor NT3 is connected to the second node Q. Other structures are similar and not repeated herein.

In the present embodiment, the control terminal of the third thin film transistor NT3 is connected to the second node Q to receive the second control signal. Obviously, when the second node Q is at the high voltage level, the third thin film transistor NT3 is turned on. When the first node P is at the low voltage level, the fourth thin film transistor NT4 and the fifth thin film transistor NT5 are turned off. Meanwhile, the first node P and the second node work normally. When the voltage level of the first node P is increased because a competitive relationship of the sixth thin film transistor NT6 and the eighth thin film transistor NT8 changes, the third thin film transistor NT3 and the fourth thin film transistor NT4 are turned on simultaneously. The second node Q receives the constant high voltage level signal VGH via the third thin film transistor NT3 and the fourth thin film transistor NT4, thereby ensuring that the point Q remains at a high voltage level and increasing stability of the GOA circuit. When compared to the control terminal of the third thin film transistor NT3 connected to the (n−1)th stage gate drive signal G(n−1) in the above-mentioned embodiment, the control terminal of the third thin film transistor NT3 connected to the second node Q in the present embodiment can cause the point Q to remain at the high voltage level for longer time because time of the point Q at the high voltage level is longer than time of the (n−1)th stage gate drive signal G(n−1) at the high voltage level. Accordingly, the stability of the GOA circuit can be increased.

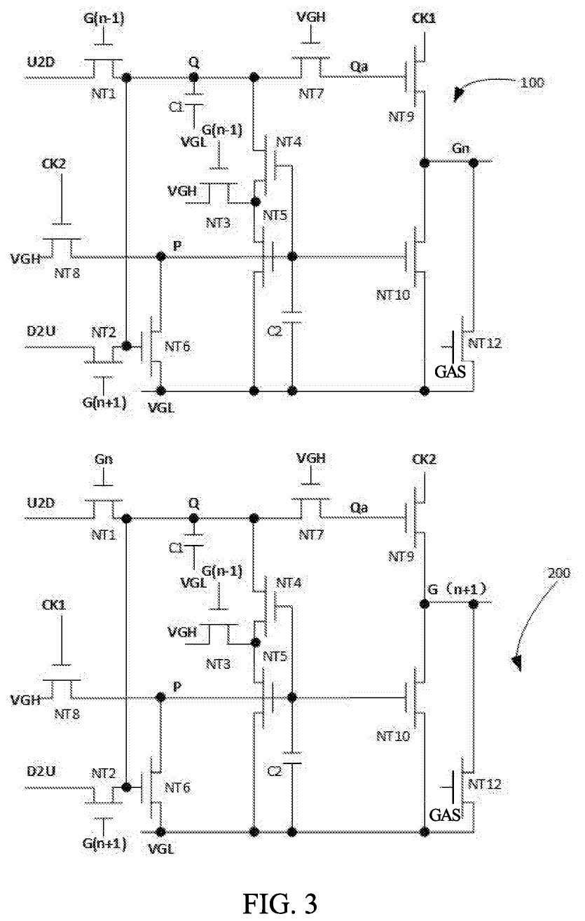

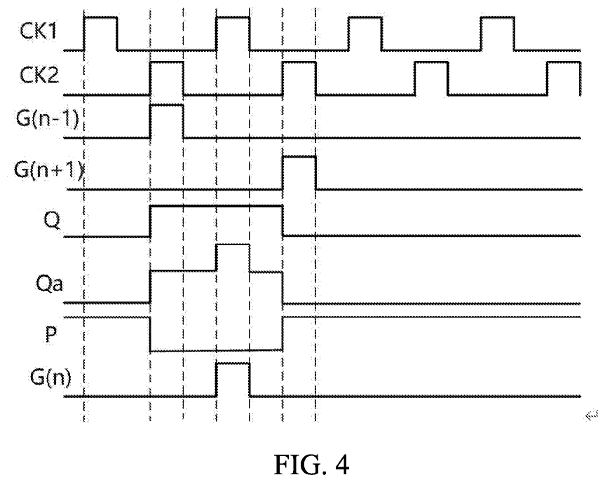

Further, please refer to FIG. 3 and FIG. 4. FIG. 3 illustrates a structural diagram of a two-clock signal architecture including an nth stage GOA unit and an (n+1)th stage GOA unit in a GOA circuit provided by an embodiment of the present disclosure. FIG. 4 illustrates a signal timing diagram of the two-clock signal architecture including the nth stage GOA unit and the (n+1)th stage GOA unit in the GOA circuit in FIG. 3.

In the embodiment of the present disclosure, the GOA circuit is a two-clock signal architecture. In the GOA circuit, a minimum repeat unit includes two GOA units including the nth stage GOA unit 100 and the (n+1)th stage GOA unit 200. A number of the minimum repeat units is m/2. Driving the nth stage GOA unit 100 and the (n+1)th stage GOA unit 200 only depend on two clock signals including a first clock signal CK1 and a second clock signal CK2.

When the first clock signal CK1 is at a high voltage level, an nth stage gate drive signal Gn outputted by the nth stage GOA unit 100 is at a high voltage level. A first thin film transistor NT1 in the (n+1)th stage GOA unit 200 is turned on. A sixth thin film transistor NT6 in the (n+1)th stage GOA unit 200 is turned on. The sixth thin film transistor NT6 in the (n+1)th stage GOA unit 200 outputs a low voltage level to a first node P. Meanwhile, the first clock signal CK1 causes an eighth thin film transistor NT8 in the (n+1)th stage GOA unit 200 to be turned on, so as to output a high voltage level to the first node P. When the sixth thin film transistor NT6 in the (n+1)th stage GOA unit 200 and the eighth thin film transistor NT8 in the (n+1)th stage GOA unit 200 are decayed, a competitive relationship changes. Accordingly, a voltage level of the first node P in the (n+1)th stage GOA unit 200 is increased. At the same time, a third thin film transistor NT3 and a fourth thin film transistor NT4 are turned on simultaneously. A second node Q receives a constant high voltage level signal VGH via the third thin film transistor NT3 and the fourth thin film transistor NT4, thereby ensuring that the point Q remains at a high voltage level and increasing stability of the GOA circuit.

Certainly, the minimum repeat unit can include two GOA units as shown in FIG. 2. A number of the minimum repeat units is m/2. The present disclosure is not limited thereto.

Further, the present disclosure further provides a display panel. The display panel includes any one of the above-mentioned GOA circuits.

Further, the present disclosure further provides a display device. The display device includes any one of the above-mentioned display panels.

Differing from the prior art, the present disclosure provides a GOA circuit. The GOA circuit includes m cascaded GOA units. An nth stage GOA unit of the GOA units includes: a first node signal control module configured to input a voltage to a first node according to an (n+1)th stage clock signal, wherein m≥n≥1; a first pull-down module configured to pull down a voltage level of the first node; a forward-backward scan control module configured to input a first control signal to the first pull-down module and a second node according to a forward-backward scan control signal, an (n−1)th stage gate drive signal, and an (n+1)th stage gate drive signal; and a second pull-down module, the second pull-down module including a third thin film transistor, a fourth thin film transistor, and a fifth thin film transistor, wherein an input terminal of the third thin film transistor receives a constant high voltage level signal, a control terminal of the third thin film transistor receives a second control signal, an output terminal of the third thin film transistor, an input terminal of the fourth thin film transistor, and an input terminal of the fifth thin film transistor are connected together, an output terminal of the fourth thin film transistor is connected to the second node, and an output terminal of the fifth thin film transistor receives a constant low voltage level signal. In the present disclosure, when the voltage level of the first node is increased because a competitive relationship of controlling the first node by the first node signal control module and the first pull-down module changes, the third thin film transistor and the fourth thin film transistor are turned on simultaneously. The second node (that is, point Q) receives the constant high voltage level signal via the third thin film transistor and the fourth thin film transistor, thereby ensuring that the point Q remains at a high voltage level and increasing stability of the GOA circuit.

It is noted that only the above-mentioned structure of the display panel in the above-mentioned embodiment is described. The display panel in accordance with the embodiment of the present disclosure may further include, according to requirements, other essential structures which are not specifically limited herein.

During specific implementation, the various units in the foregoing may be implemented as independent entities, or may also be randomly combined to be implemented as one or several entities. For specific implementation of the various units in the foregoing, reference may be made to the foregoing embodiments, and elaborate description is no longer provided herein.

A GOA circuit, a display panel, and a display device provided by the embodiments of the present disclosure are described above in detail. In this specification, specific examples are used for illustrating principles and implementation manners of the present disclosure. The foregoing descriptions of the embodiments are merely used to help understand the methods and core ideas of the present disclosure. Meanwhile, those skilled in the art may make modifications to the specific implementation manners and application scopes according to the idea of the present disclosure. In conclusion, the content of this specification should not be construed as a limitation on the present invention.

What is claimed is:

1. A GOA circuit, wherein the GOA circuit comprises m cascaded GOA units, and an nth stage GOA unit of the GOA units comprises:
a first node signal control module configured to input a voltage to a first node according to an (n+1)th stage clock signal, wherein m≥n≥1;
a first pull-down module configured to pull down a voltage level of the first node;
a forward-backward scan control module configured to input a first control signal to the first pull-down module and a second node according to a forward-backward scan control signal, an (n−1)th stage gate drive signal, and an (n+1)th stage gate drive signal; and
a second pull-down module, the second pull-down module comprising a third thin film transistor, a fourth thin film transistor, and a fifth thin film transistor, wherein an input terminal of the third thin film transistor receives a constant high voltage level signal, a control terminal of the third thin film transistor receives a second control signal, an output terminal of the third thin film transistor, an input terminal of the fourth thin film transistor, and an input terminal of the fifth thin film transistor are connected together, an output terminal of the fourth thin film transistor is connected to the second node, and an output terminal of the fifth thin film transistor receives a constant low voltage level signal.

2. The GOA circuit of claim 1, wherein the second control signal is the (n−1)th stage gate drive signal.

3. The GOA circuit of claim 1, wherein the control terminal of the third thin film transistor is connected to the second node to receive the second control signal.

4. The GOA circuit of claim 2, wherein the third thin film transistor, the fourth thin film transistor, and the fifth thin film transistor are N-type thin film transistors.

5. The GOA circuit of claim 1, wherein the first pull-down module comprises a sixth thin film transistor, a control terminal of the sixth thin film transistor is connected to the forward-backward scan control module, an input terminal of the sixth thin film transistor receives the constant low voltage level signal, and an output terminal of the sixth thin film transistor is connected to the first node.

6. The GOA circuit of claim 5, wherein the forward-backward scan control module comprises a first thin film transistor and a second thin film transistor;
an input terminal of the first thin film transistor receives a forward scan signal, and a control terminal of the first thin film transistor receives the (n−1)th stage gate drive signal;
an input terminal of the second thin film transistor receives a backward scan signal, and a control terminal of the second thin film transistor receives the (n+1)th stage gate drive signal; and
an output terminal of the first thin film transistor, an output terminal of the second thin film transistor, and a control terminal of the sixth thin film transistor are connected together.

7. The GOA circuit of claim 6, wherein the first node signal control module comprises an eighth thin film transistor, the output terminal of the first thin film transistor, the output terminal of the second thin film transistor, and a control terminal of the output terminal of the eighth thin film transistor are connected together, an input terminal of the eighth thin film transistor receives the constant high voltage level signal, and an output terminal of the eighth thin film transistor is connected to the first node.

8. The GOA circuit of claim 1, wherein the nth stage GOA unit comprises a first capacitor and a second capacitor, one terminal of the first capacitor is connected to the second node, the other terminal of the first capacitor receives the constant low voltage level signal, one terminal of the second capacitor is connected to the first node, and the other terminal of the second capacitor receives the constant low voltage level signal.

9. A display panel, wherein the display panel comprises a GOA circuit, the GOA circuit comprises m cascaded GOA units, and an nth stage GOA unit of the GOA units comprises:
a first node signal control module configured to input a voltage to a first node according to an (n+1)th stage clock signal, wherein m≥n≥1;
a first pull-down module configured to pull down a voltage level of the first node;
a forward-backward scan control module configured to input a first control signal to the first pull-down module and a second node according to a forward-backward scan control signal, an (n−1)th stage gate drive signal, and an (n+1)th stage gate drive signal; and
a second pull-down module, the second pull-down module comprising a third thin film transistor, a fourth thin film transistor, and a fifth thin film transistor, wherein an input terminal of the third thin film transistor receives a constant high voltage level signal, a control terminal of the third thin film transistor receives a second control signal, an output terminal of the third thin film transistor, an input terminal of the fourth thin film transistor, and an input terminal of the fifth thin film transistor are connected together, an output terminal of the fourth thin film transistor is connected to the second node, and an output terminal of the fifth thin film transistor receives a constant low voltage level signal.

10. The display panel of claim 9, wherein the second control signal is the (n−1)th stage gate drive signal.

11. The display panel of claim 9, wherein the control terminal of the third thin film transistor is connected to the second node to receive the second control signal.

12. The display panel of claim 10, wherein the third thin film transistor, the fourth thin film transistor, and the fifth thin film transistor are N-type thin film transistors.

13. The display panel of claim 9, wherein the first pull-down module comprises a sixth thin film transistor, a control terminal of the sixth thin film transistor is connected to the forward-backward scan control module, an input terminal of the sixth thin film transistor receives the constant low voltage level signal, and an output terminal of the sixth thin film transistor is connected to the first node.

14. The display panel of claim 13, wherein the forward-backward scan control module comprises a first thin film transistor and a second thin film transistor;
an input terminal of the first thin film transistor receives a forward scan signal, and a control terminal of the first thin film transistor receives the (n−1)th stage gate drive signal;
an input terminal of the second thin film transistor receives a backward scan signal, and a control terminal of the second thin film transistor receives the (n+1)th stage gate drive signal; and
an output terminal of the first thin film transistor, an output terminal of the second thin film transistor, and a control terminal of the sixth thin film transistor are connected together.

15. The display panel of claim 14, wherein the first node signal control module comprises an eighth thin film transistor, the output terminal of the first thin film transistor, the output terminal of the second thin film transistor, and a control terminal of the output terminal of the eighth thin film transistor are connected together, an input terminal of the eighth thin film transistor receives the constant high voltage level signal, and an output terminal of the eighth thin film transistor is connected to the first node.

16. The display panel of claim 9, wherein the nth stage GOA unit comprises a first capacitor and a second capacitor, one terminal of the first capacitor is connected to the second node, the other terminal of the first capacitor receives the constant low voltage level signal, one terminal of the second capacitor is connected to the first node, and the other terminal of the second capacitor receives the constant low voltage level signal.

17. A display device, wherein the display device comprises a display panel, the display panel comprises a GOA circuit, the GOA circuit comprises m cascaded GOA units, and an nth stage GOA unit of the GOA units comprises:
a first node signal control module configured to input a voltage to a first node according to an (n+1)th stage clock signal, wherein m≥n≥1;
a first pull-down module configured to pull down a voltage level of the first node;
a forward-backward scan control module configured to input a first control signal to the first pull-down module and a second node according to a forward-backward scan control signal, an (n−1)th stage gate drive signal, and an (n+1)th stage gate drive signal; and
a second pull-down module, the second pull-down module comprising a third thin film transistor, a fourth thin film transistor, and a fifth thin film transistor, wherein an input terminal of the third thin film transistor receives a constant high voltage level signal, a control terminal of the third thin film transistor receives a second control signal, an output terminal of the third thin film transistor, an input terminal of the fourth thin film transistor, and an input terminal of the fifth thin film transistor are connected together, an output terminal of the fourth thin film transistor is connected to the second node, and an output terminal of the fifth thin film transistor receives a constant low voltage level signal.

18. The display device of claim 17, wherein the second control signal is the (n−1)th stage gate drive signal.

19. The display device of claim 17, wherein the control terminal of the third thin film transistor is connected to the second node to receive the second control signal.

20. The display device of claim 18, wherein the third thin film transistor, the fourth thin film transistor, and the fifth thin film transistor are N-type thin film transistors.
